(19) United States
(12) Patent Application Publication
(10) Pub. No.: US 2001/0020855 A1
(43) Pub. Date: Sep. 13, 2001

(54) Fast signal selector

(76) Inventor: Kamel Ayadi, Puchheim (DE)

Correspondence Address: LERNER AND GREENBERG, P.A., Post Office Box 2480, Hollywood, FL, 33022-2480, US

(21) Appl. No.: 09/778,535

(22) Filed: Feb. 7, 2001

(30) Foreign Application Priority Data
Feb. 9, 2000 (DE) 100 05 616.4

(51) Int. Cl. H03K 3/00

(52) U.S. Cl. 327/99; 327/408

(57) ABSTRACT

The invention relates to a fast signal selector having a plurality of transfer gates which are connected in parallel. The input signals are applied to the signal inputs of the transfer gates and a selection signal is applied to control inputs of the transfer gates. Due to the switching properties of the transfer gates, the input signals can be switched through onto a common output line essentially without any power loss and with a very short time delay of approximately 20 ps.

### BACKGROUND OF THE INVENTION

1. Field of the Invention

The invention relates to a circuit configuration for selecting and outputting one of a plurality of input signals onto an output line.

When developing and implementing extremely fast DRAMs (Dynamic Random Access Memory), there is the problem that during a signal selection using conventional multiplexers, a time delay, which is critical with regard to the short memory access times of such DRAMs, occurs between the input signals to be selected and the corresponding output signal. Further, a high power loss occurs. This additional delay time can disrupt internal functions of the DRAM. The additional power loss means that, under certain circumstances, the testing of the DRAM product and the determination of characteristic values of the DRAM product, may still be possible, but are definitely made more difficult.

In the burn-in phase, most of the transistors integrated in the DRAM are subjected to a thermal-electrical loading. The DRAM is operated in the so-called DA (Direct Access) mode in this case. The goal is to achieve that the threshold voltage V_{TH} of a “fresh” transistor remains constant over an operating time of two years. This can be achieved within a few hours during the burn-in phase by toggling the transistor gates with a regular clock signal.

### SUMMARY OF THE INVENTION

It is accordingly an object of the invention to provide a circuit configuration for a fast signal selection which overcomes the above-mentioned disadvantages of the heretoforeknown circuit configurations of this general type and which is suitable in particular for use within a DRAM module and which minimizes the time delay between the input signals to be selected and the output signal and which minimizes the power loss and which allows, during the burn-in phase, to select in a simple and cost-effective manner an internal clock signal of the DRAM module in order to toggle the transistor gates.

With the foregoing and other objects in view there is provided, in accordance with the invention, a circuit configuration, including:

a plurality of transfer gates having respective signal inputs for receiving respective input signals, respective control inputs for receiving a selection signal, and respective output terminals, the transfer gates being connected in parallel and selecting, based on the selection signal, one of the input signals as an output signal;

an output line for outputting the output signal; and

the output terminals being connected to one another and being connected to the output line.

In other words, the object of the invention is achieved by a circuit configuration for selecting and outputting one of a plurality of fed-in input signals onto an output line through the use of a selection signal, the circuit configuration being characterized in that a plurality of transfer gates are connected in parallel, in that the input signals are applied to the signal inputs of the transfer gates and the selection signal is applied to the control inputs of the transfer gates, and in that the output terminals of the transfer gates are connected to one another and to the output line.

With the objects of the invention in view there is also provided, in a DRAM component providing an internal clock signal, a circuit configuration, including:

a base circuit with two transfer gates having respective signal inputs for receiving respective input signals, respective control inputs for receiving a selection signal, and respective output terminals, the transfer gates including complementary MOS transistors, and the transfer gates being connected in parallel and selecting, based on the selection signal, one of the input signals as an output signal;

an output line for outputting the output signal;

the output terminals being connected to one another and being connected to the output line; and

the base circuit being configured such that the internal clock signal, as a first one of the input signals, is switched to the output line during a burn-in phase in a direct access operating mode through the use of the selection signal as an operating mode selection signal, and such that a second one of the input signals is switched, during a normal operating mode of the DRAM component, to the output line.

According to another feature of the invention, two of the transfer gates form a basic circuit for selecting between two of the input signals, and the two of the transfer gates include complementary MOS transistors.

One of the input signals to be selected may be an internal clock signal which is applied to the transistor gates of the DRAM module during the burn-in phase for the purpose of toggling.

According to a further feature of the invention, the input signals have given signal levels, and the transfer gates and the given signal levels are configured such that a minimal delay is provided between the input signals and the output signal. The transfer gates and the given signal levels are in particular set such that the delay between the input signals and the output signal is approximately 20 ps.

The circuit configuration according to the invention has thus the advantage that it causes only a minimal time delay of approximately 20 ps between the input signals to be selected and the corresponding output signal, and practically no power loss occurs.

The transfer gates serving for selecting the input signals can be integrated simply and cost-effectively in a concentrated interface circuit in the DRAM chip and occupy only a small chip area.

A basic circuit of the fast signal selector configuration in the DRAM has, for selecting two input signals, two transfer gates including complementary CMOS transistors and the selection signal is an operating mode signal (DAMODE). The first input signal is an internal clock signal, e.g. a clock signal (SCKS), which is selected by the fast signal selector configuration according to the invention during a direct access memory mode (DA mode) through the use of the operating mode selection signal.

Due to the high switching speed and the practically non-existent power loss of the transfer gates used for the circuit configuration according to the invention, this circuit configuration, which functions like a signal multiplexer, can advantageously be used within DRAM chips.

Other features which are considered as characteristic for the invention are set forth in the appended claims.

Although the invention is illustrated and described herein as embodied in a fast signal selector, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a schematic circuit diagram of a preferred exemplary embodiment of a basic circuit according to the invention, having two complementary transfer gates for selecting two input signals;

FIG. 2 is a timing chart with signal timing diagrams for illustrating the function of the exemplary embodiment of the circuit configuration according to the invention as illustrated in FIG. 1;

FIG. 3 is an enlarged detail of a signal timing diagram illustrating the time delay between one of the input signals of the circuit configuration in FIG. 1 and the corresponding output signal;

FIG. 4 is a circuit diagram of an extended signal selection circuit based on the basic circuit of FIG. 1; and

FIG. 5 is a circuit diagram of a complete interface circuit of a DRAM based on the basic circuit of FIG. 1.

### DESCRIPTION OF THE PREFERRED EMBODIMENTS

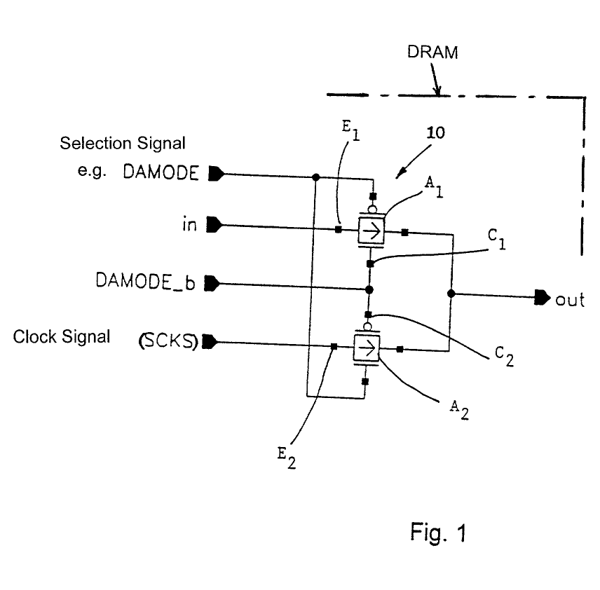

Referring now to the figures of the drawings in detail and first, particularly, to FIG. 1 thereof, there is shown a circuit diagram of a preferred exemplary embodiment of a basic circuit according to the invention designated by reference numeral 10, which has two transfer gates A₁ and A₂ which are connected in parallel and include complementary MOS transistors, serving for the selection of two input signals “in” and “SCKS” through the use of an operating mode selection signal. The operating mode selection signal, in the example DAMODE and its inverted signal DAMODE_b, are present at respective control inputs C₁, C₂ of the transfer gates A₁ and A₂. The respectively selected input signal “in” or “SCKS” is switched onto an output line “out”.

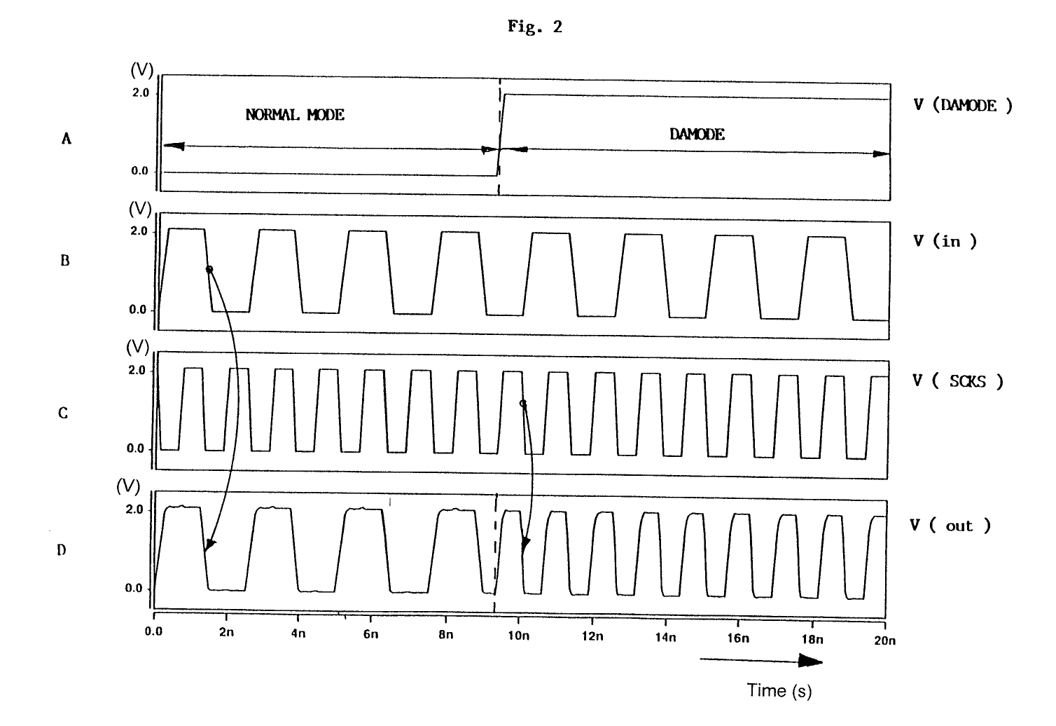

FIG. 2 show signal timing diagrams A, B, C and D for illustrating the function of the basic circuit 10 illustrated in FIG. 1. The top line (timing diagram A) shows the selection signal DAMODE. With the high state of the selection signal DAMODE, the signal selector illustrated in FIG. 1 switches through the clock signal SCKS (timing diagram C) present at the input E₂ of the bottom transfer gate A₂ and puts the clock signal onto the output line “out”, whereas the low state of the selection signal DAMODE, which is designated by DAMODE_b in FIG. 1 and FIG. 2, switches through the input signal “in” (timing diagram B) present at the input E₁ of the first transfer gate A₁ and puts it onto the output line “out”. This function is evident from timing diagram D.

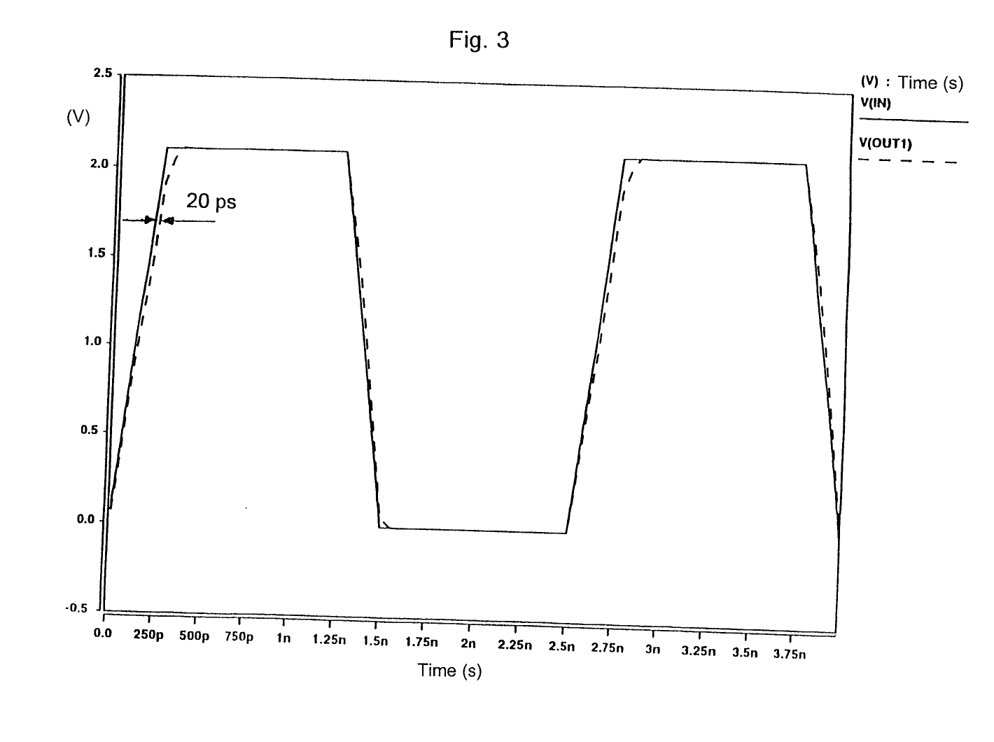

As shown in FIG. 3, only a slight time delay of about 20 ps between the respective input signal V(IN) and the output V(OUT1) of the transfer gates A₁ and A₂ is caused on account of the fast switching time of the transfer gates used for the signal selector according to the invention. This high speed makes the basic circuit 10 illustrated in FIG. 1 particularly suitable for toggling transistors integrated in the DRAM during the burn-in phase.

Test experiments and a simulation have shown that a DRAM developed by the applicant and having a storage capacity of 288 Mbits and a clock frequency of 800 MHz operates correctly with the fast signal selector according to the invention. A time delay between an input signal and the corresponding output signal, which time delay usually occurs in conventional multiplexers, is of no significance with this signal selection circuit.

The fast signal selector according to the invention enables this toggling of the transistor gates through the use of the internal SCKS clock signal in the high state of the selection signal DAMODE during the burn-in phase, which lasts from three to ten hours.

After this pulsed loading of the transistors in the DRAM, V_{TH} remains constant for a long time, e.g.>2 years, and thereby increases the work quality of the DRAM.

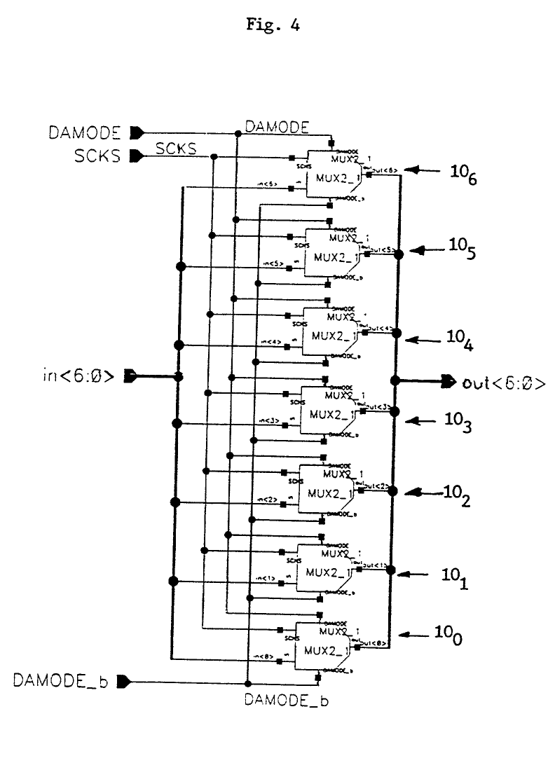

The basic circuit 10 of the fast signal selector according to the invention as shown in FIG. 1 allows an application in which the clock signal SCKS is switched onto a bus. This application is illustrated in FIG. 4.

In the extended signal selection circuit illustrated in FIG. 4, each of the signal selection circuits designated by 10₀ to 10₆ is represented by the basic circuit 10 shown in FIG. 1. Via a bus line “in” <6:0>, which is distributed between all first inputs of the signal selection circuit 10₀ to 10₆, seven signals can be switched onto an output bus “out” <6:0> in the normal mode. The entire circuit is controlled by the selection signal DAMODE and the inverted signal DAMODE_b thereof. During DAMODE, SCKS is put onto the output bus.

From functional and circuitry standpoints, each of the signal selection circuits 10₀ to 10₆ shown in FIG. 4 is identical to the basic circuit 10 illustrated in FIG. 1. When DAMODE is in the low state (DAMODE_b is high), “in” <6:0> is switched onto the output bus line “out” <6:0>. On the other hand, when the selection signal DAMODE is high, the internal clock signal SCKS is put onto the output bus line “out” <6:0>.

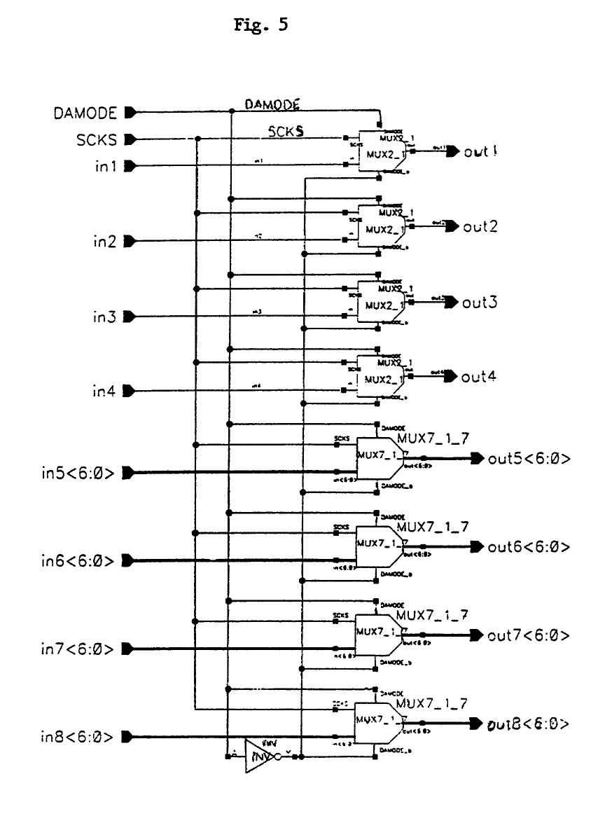

FIG. 5 shows a circuit diagram of a complete interface circuit for the application for switching the internal clock signal SCKS to the transistor gates during the burn-in phase of the DRAM, that is based on the basic circuit of a fast signal selector according to the invention as shown in FIG. 1. This interface circuit contains four basic circuits 10 in accordance with FIG. 1, which are symbolized by MUX₂₋₁, and four extended signal selection circuits in accordance with FIG. 4, which are symbolized by MUX₇₋₁. In this interface circuit, when the selection signal DAMODE is high, toggling is effected by the clock signal SCKS with a delay time of about 20 ps. When the selection signal DAMODE is low, the inputs “in” (in1, in2, . . . in8) are connected to their respective outputs (out1, out2, . . . out8).

In general, in order to be able to work with the basic circuit shown in FIG. 1, the input signals and the clock signal SCKS merely have to be amplified to a sufficient extent that they can be switched through by the transfer gates without attenuation and without any additional delay time.

The above description makes it clear to a person of skill in the art that the basic circuit of a fast signal selector as illustrated in FIG. 1 allows many different circuit combinations, but that the function thereof is the same as in the basic circuit shown in FIG. 1.

The basic circuit 10 of a fast signal selector according to the invention as shown in FIG. 1 can also be used in other operating modes during the burn-in of a DRAM, e.g. in the so-called DROWSY MODE. The DROWSY MODE signal then simply replaces the selection signal DAMODE in the circuit configurations illustrated in FIGS. 1, 4 and 5.

The correct operation of the circuit configuration according to the invention was verified by simulation in normal mode tests and in DA mode tests.

I claim:

1. A circuit configuration, comprising:
a plurality of transfer gates having respective signal inputs for receiving respective input signals, respective control inputs for receiving a selection signal, and respective output terminals, said transfer gates being connected in parallel and selecting, based on the selection signal, one of the input signals as an-output signal;
an output line for outputting the output signal; and
said output terminals being connected to one another and being connected to said output line.

2. The circuit configuration according to claim 1, wherein:
two of said transfer gates form a basic circuit for selecting between two of the input signals; and
said two of said transfer gates include complementary MOS transistors.

3. The circuit configuration according to claim 1, wherein the input signals have given signal levels, and said transfer gates and the given signal levels are set such that a minimal delay is provided between the input signals and the output signal.

4. The circuit configuration according to claim 1, wherein the input signals have given signal levels, and said transfer gates and the given signal levels are set such that a delay between the input signals and the output signal is substantially 20 ps.

5. In a DRAM component providing an internal clock signal, a circuit configuration, comprising:
a base circuit with two transfer gates having respective signal inputs for receiving respective input signals, respective control inputs for receiving a selection signal, and respective output terminals, said transfer gates including complementary MOS transistors, and said transfer gates being connected in parallel and selecting, based on the selection signal, one of the input signals as an output signal;
an output line for outputting the output signal;
said output terminals being connected to one another and being connected to said output line; and
said base circuit being configured such that the internal clock signal, as a first one of the input signals, is switched to said output line during a burn-in phase in a direct access operating mode through the use of the selection signal as an operating mode selection signal, and such that a second one of the input signals is switched, during a normal operating mode of the DRAM component, to said output line.

6. The circuit configuration according to claim 5, wherein the input signals have given signal levels, and said transfer gates and the given signal levels are set such that a minimal delay is provided between the input signals and the output signal.

7. The circuit configuration according to claim 5, wherein the input signals have given signal levels, and said transfer gates and the given signal levels are set such that a delay between the input signals and the output signal is substantially 20 ps.
